(19) United States
(12) Patent Application Publication
(10) Pub. No.: US 2025/0258989 A1
(43) Pub. Date: Aug. 14, 2025

(54) SPARE ENGINEERING CHANGE ORDER CELL COVERAGE WITHIN INTEGRATED CIRCUIT DESIGNS

(71) Applicant: International Business Machines Corporation, Armonk, NY (US)

(72) Inventors: Brian VERAA, Round Rock, TX (US); Julie Ann ROSSER, Austin, TX (US)

(21) Appl. No.: 18/436,424

(22) Filed: Feb. 8, 2024

(51) Int. Cl. G06F 30/398; G06F 30/392

(52) U.S. Cl. CPC G06F 30/398; G06F 30/392

(57) ABSTRACT

Embodiments of the present disclosure are directed to methods, systems, and computer program products for implementing spare ECO cell coverage validation within an IC) layout. A disclosed embodiment enables spare ECO cell coverage validation using density-based Design Rule Checking (DRC) techniques for validating both a minimum quantity and effective distribution of spare ECO cells in a given IC layout, effectively and efficiently providing ECO cell coverage verification, and accurately identifying failing spare ECO cell coverage. Disclosed embodiments automate the process of validating both a threshold or sufficient spare cell quantity and effective distribution of the spare ECO cells within an IC design layout.

### BACKGROUND

The present invention relates to integrated circuit design, and more specifically, to implementing spare engineering change order (ECO) cell coverage validation within an integrated circuit (IC) layout of chip designs.

Spare ECO cells, also called gate array fill cells, are provided within IC designs to enable making needed circuit or logic design modifications after sending an IC layout to a semiconductor foundry for fabrication of the IC chip. The spare ECO cells are used for making logical design changes, such as by modifying transistor content of Very-large-scale integration (VLSI) circuit logic designs, during tape-outs that only update a subset of the metal layout masks by adding selected ECO cells. The spare ECO cells may include gate array fill cells, spare buffers or inverters, spare latches, and the like. Available spare ECO cells may be successfully used for such updates only when a sufficient quantity of spare cells are available in physical proximity where needed for specific IC circuitry requiring design changes. In the IC design process, ensuring that sufficient spare cells exist within the IC layout is part of confirming that the IC design is ready for tape-out, (i.e., some conventional systems use place and route environment scripting for checking the quantity of spare ECO cells while using manual, visual review for checking the distribution of spare ECO cells). New techniques are needed to implement spare cell coverage validation within an IC design, using automated computing processing techniques.

### SUMMARY

Embodiments of the present disclosure are directed to methods, systems, and computer program products for implementing spare ECO cell coverage validation within an integrated circuit (IC) design.

According to one embodiment of the present disclosure, a non-limiting computer implemented method is provided. The method comprises defining an engineering change order (ECO) cell checking layer to represent spare ECO cells being checked based on physical design data of an integrated circuit (IC) layout; defining a standard cell placement area checking layer to represent an available standard cell placement area of standard cells based on the physical design data; and performing density-based design rule checking (DRC), based on a threshold density ratio of the spare ECO cells of the ECO checking layer and the standard cells of the standard cell placement area checking layer, to validate spare ECO coverage of the IC design.

Other disclosed embodiments include a computer system and computer program product for implementing spare ECO cell coverage validation within an IC design, implementing features of the above-disclosed method.

### BRIEF DESCRIPTION OF THE DRAWINGS

FIG. 1 is a block diagram of an example computer environment for use in conjunction with one or more disclosed embodiments;

FIG. 2 is a schematic and block diagram of an example system for implementing spare ECO cell coverage validation for an IC design according to one or more disclosed embodiments;

FIG. 3 is a flowchart illustrating example operations of a method for implementing spare ECO cell coverage validation according to one or more disclosed embodiments;

FIG. 4 is a flowchart illustrating further details of example operations of a method for implementing spare ECO cell coverage validation according to one or more disclosed embodiments

FIG. 5 is a schematic and block diagram illustrating example regions of an IC layout and example operations for implementing spare ECO cell coverage validation according to one or more disclosed embodiments; and

FIG. 6 is a flowchart illustrating a method for implementing spare ECO cell coverage validation of a disclosed embodiment.

### DETAILED DESCRIPTION

Embodiments herein describe techniques for validating a minimum level of spare ECO cell coverage and placement of the spare cells in an IC design using computer software tools. An IC design can require logical design changes for various reasons. Spare ECO cells provide the ability to make changes to the transistor content of VLSI designs using metal layer updates. The embodiments herein describe techniques and a quantitative method where computer software tools validate a minimum level of ECO cell coverage in a chip design that includes an effective distribution of the ECO cells across an IC layout of the chip design. Disclosed embodiments describe novel techniques, using Design Rule Checking (DRC) tools comprising computer code, to ensure sufficient spare cell quantity and effective distribution of the spare ECO cells within an IC layout of the chip design.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

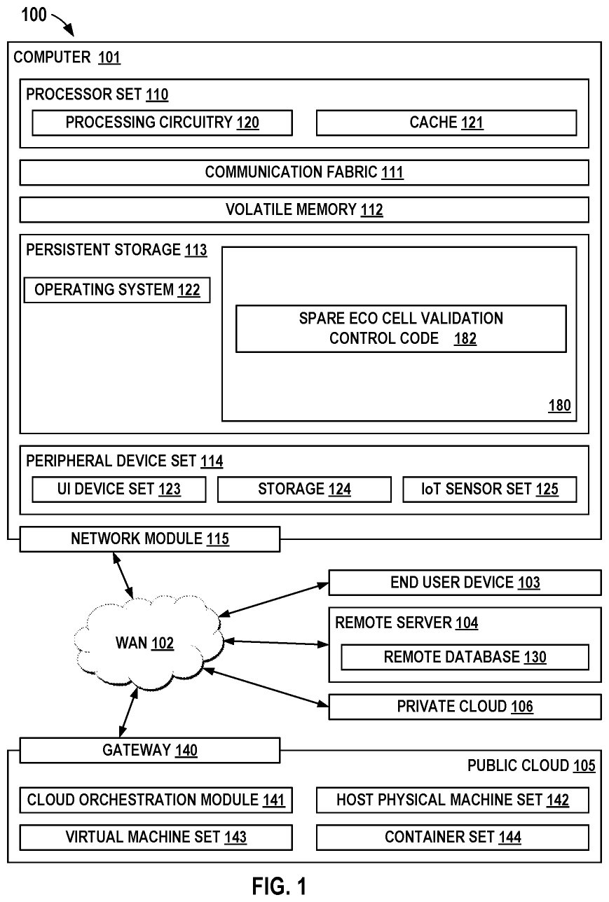

Referring to FIG. 1, a computing environment 100 contains an example of an environment for the execution of at least some of the computer code involved in performing the inventive methods, such as a Spare ECO Cell Validation Control Code 182, at block 180. In addition to block 180, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 180, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 180 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 180 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

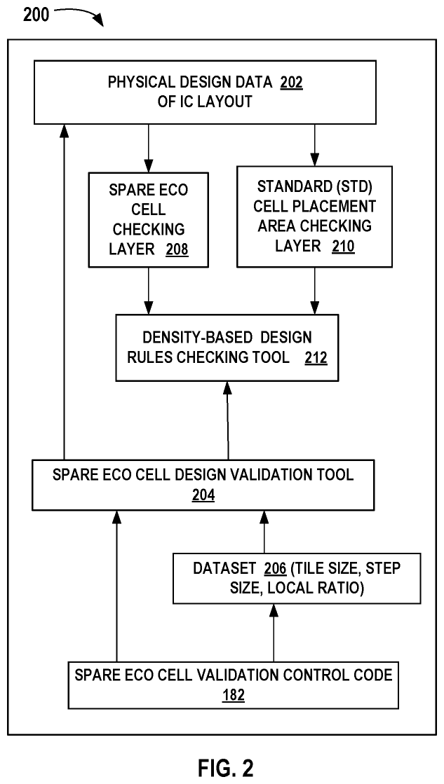

FIG. 2 illustrates an example system 200 for implementing spare ECO cell coverage for an IC design of disclosed embodiments. System 200 can be used in conjunction with the computer 101 and cloud environment of the computing environment 100 of FIG. 1 with the Spare ECO Cell Validation Control Code 182 for implementing methods according to one or more embodiments.

System 200 performs disclosed enhanced methods for validating spare ECO cell coverage before sending an IC layout to a semiconductor foundry for fabrication of the IC chip. System 200 implements spare ECO cell coverage validation using novel density-based DRC techniques for validating both a minimum quantity and effective distribution of spare ECO cells in a given IC layout, effectively and efficiently providing ECO cell coverage verification, and accurately identifying failing spare ECO cell coverage. System 200 automates the process of identifying sufficient spare ECO cell coverage, enabling enhanced analysis, and reduced processing time over conventional spare ECO cell coverage.

System 200 includes physical design data 202 for a given IC layout for a given IC or chip to be manufactured, which is used to implement spare ECO cell coverage validation in accordance with disclosed embodiments. For example, system 200 obtains the physical design data 202 comprising spare ECO cell shapes, standard cell shapes, circuit shapes, active logic shapes, sub-circuits, cell and macro designs, and the like, which represent regions to be manufactured on different layers of the IC layout. Spare ECO cells typically include gate array fill cells, spare buffers or inverters, spare latches, and the like.

System 200 includes a Spare ECO Cell Design Validation Tool 204 used with the Spare ECO Cell Validation Control Code 182 for implementing disclosed methods. In an embodiment, a dataset 206 stores a plurality of defined validation parameters including one or more of tile size, step size, overall or global ratio, one or more local ratios, and the like, coupled to the Spare ECO Cell Design Validation Tool 204. System 200 generates or builds a spare ECO cell checking layer 208, and a standard cell placement area checking layer 210 of disclosed embodiments (e.g., using the Spare ECO Cell Design Validation Tool 204 and the physical design data 202). In an embodiment, the spare ECO cell checking layer 208 represents spare ECO cells being checked that are identified based on the physical design data 202 of an integrated circuit (IC) layout. In an embodiment, system 200 can identify a specific type of spare ECO cells, such as spare ECO gate array fill cells or spare ECO buffer cells. In an embodiment, the spare ECO cell checking layer 208 can be implemented by a non-manufacturable marker layer in the cell layout itself, or dynamically generated as part of a checking run based on cell name, or spare ECO cell shapes of an IC layout. In an embodiment, the standard cell placement area checking layer 210 represents regions of the IC layout including active circuit logic functions formed by interconnected standard cells (i.e., functional logic cells) of multiple different circuit rows, and different voltage rails that are identified based on the physical design data 202 of the IC layout.

System 200 includes a density-based Design Rule Checking (DRC) tool 212 controlled by the Spare ECO Cell Design Validation Tool 204 with the Spare ECO Cell Validation Control Code 182 for implementing disclosed methods. The density-based Design Rule Checking (DRC) tool 206 comprising computer code, which performs one or more novel density-based DRC operations based on the spare ECO cell checking layer 208 and the standard cell checking layer 210 to validate spare ECO cell coverage of the IC layout. In an embodiment, the density-based DRC operations identify an overall or global ratio based on the spare ECO cell checking layer 208 and the standard cell checking layer 210. In an embodiment, the density-based DRC operations identify a plurality of local ratios based on the spare ECO cell checking layer 208 and the standard cell checking layer 210. The defined validation parameters, including one or more of tile size, step size, overall or global thermal density ratio, and local thermal density ratios, are accessed by the Spare ECO Cell Design Validation Tool 204 and used to identify DRC rule violations or failures of disclosed embodiments.

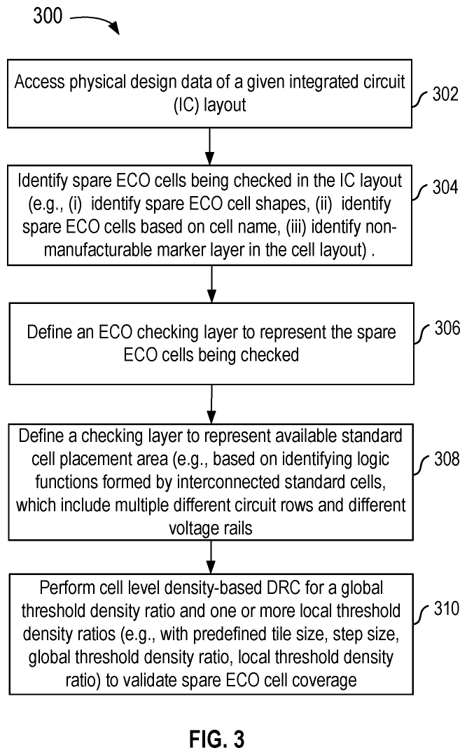

FIGS. 3, 4, 5, and 6 illustrates example operations of respective methods 300, 400, 502, and 600 for implementing spare ECO cell coverage validation before sending an IC layout to a semiconductor foundry for fabrication of the IC chip, according one or more disclosed embodiments. For example, the disclosed methods can be implemented by system 200 including the Spare ECO Cell Validation Control Code 182 used with the computer 101 in accordance with one or more disclosed embodiments. In FIGS. 3, 4, 5, and 6, the same reference numbers are used for identical or similar components as used in FIG. 2.

Referring to FIG. 3, operations of method 300 begin at block 302 where system 200 accesses an IC layout comprising physical design data that includes spare ECO cell shapes, standard cell shapes, circuit shapes, active logic shapes, sub-circuits, cell and macro designs, and the like. At block 304, system 200 identifies spare ECO cells being checked in the IC layout. For example, system 200 can identify the spare ECO cells by spare type, such as spare ECO gate array fill cells or spare ECO buffer cells. In an embodiment, for example identifying the spare ECO cells is based on cell shapes in the physical design data of the IC layout, or is based on cell name. In an embodiment, the spare ECO cell or spare ECO cells being checked are identified based on a non-manufacturable marker layer in the cell layout.

At block 306, system 200 defines a spare ECO checking layer to represent spare ECO cells being checked based on the physical design data 202 of an integrated circuit (IC) layout. For example, a checking run of the physical design data of the IC layout can be performed to dynamically generate the spare ECO cell checking layer based on a cell name, or spare ECO cell shapes. A non-manufacturable marker layer in the spare ECO cell layout can implement the spare ECO cell checking layer. At block 308, system 200 defines a standard cell placement area checking layer to represent an available standard cell placement area of standard cells based on the physical design data. In an embodiment, for example defining standard cell placement area checking layer includes identifying active circuit logic functions formed by interconnected standard cells, where the circuit logic functions comprise multiple circuit rows, and voltage rails of the interconnected standard cells identified based on the physical design data. At block 310, system 200 performs density-based cell level DRC, based on a threshold density ratio of the spare ECO cells of the spare ECO checking layer and the standard cells of the standard cell placement area checking layer to validate spare ECO cell coverage of the IC layout.

In an embodiment, the density-based cell level DRC identifies a DRC violation or failure of the spare ECO cell coverage with an identified density ratio that is less than the defined threshold density ratio. For example, the threshold density ratio may be defined as 0.10 or 10%, and any identified ratio that is less than the threshold density ratio of 0.10 identifies a DRC violation or failure of the spare ECO cell coverage. In an embodiment, a different value of the threshold ratio is provided for a global or overall threshold density ratio for the IC layout than one or more local threshold density ratios for specific regions or areas of the IC layout. In an embodiment, a value of the threshold density ratio is selected based on a predicted logical design stability of defined regions of the IC layout or of the standard cell placement area checking layer. For example, a higher threshold ratio may be selected for new circuit regions that may require more design changes and spare ECO cells before fabrication of the IC or chip.

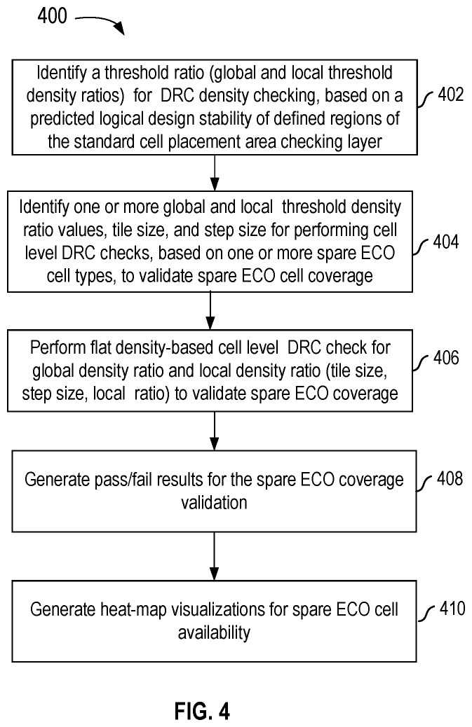

Referring to FIG. 4, operations of method 400 begin at block 402 where system 200 identifies a threshold density ratio (e.g., for a global threshold density ratio and local threshold density ratios) based on a predicted logical design stability of defined regions of the IC layout. In an embodiment, the value of the threshold density ratio is selected based on a predicted logical design stability of defined regions of the IC layout or of the standard cell placement area checking layer. For example, a higher threshold density ratio may be selected for new circuit regions that may require more design changes and spare ECO cells before fabrication of the IC or chip.

At block 404, system 200 identifies one or more global and local threshold density ratio values, tile size, and step size based on one or more spare ECO cell types, (e.g., spare ECO gate array fill cells, spare ECO buffer or inverter cells, and the like) for example, used for performing cell level DRC to validate the spare ECO cell coverage. At block 406, system 200 performs flat density-based cell level DRC to identify a global threshold density ratio (and, local density ratio) to validate spare ECO cell coverage and provide full chip analysis and signoff of the IC layout for fabrication. At block 408, system 200 generates pass and fail results for the spare ECO cell coverage validation based on the identified global density ratio and one or more local density ratios. At block 408, system 200 generates heat map visualization of spare cell availability aiding manual review and analysis beyond pass and fail results.

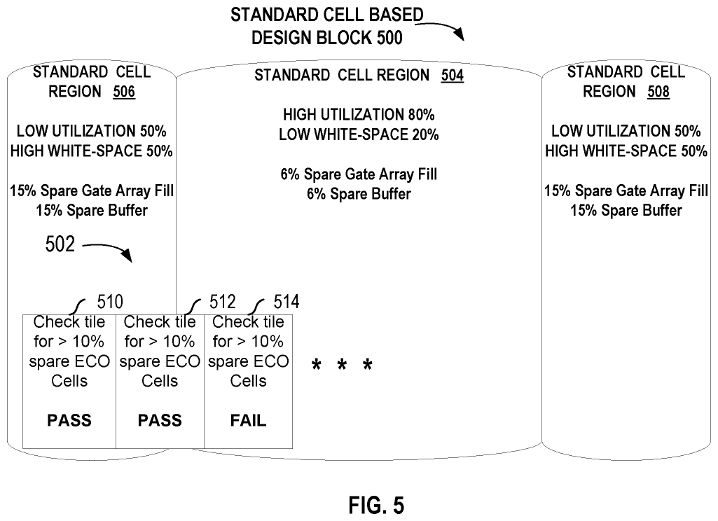

FIG. 5 illustrates an example standard cell based design block 500 of an IC layout and example operations of a method 502 for implementing spare ECO cell coverage validation according to one or more disclosed embodiments. As shown, the standard cell based design block 500 includes a standard cell region 504 occupying one-half of the block 500 that includes high utilization 80% and low whitespace 20%. The remaining one-half of the standard cell based design block 500 is equally shared by a standard cell region 506 and a standard cell region 508; as shown, both standard cell regions 506 and 508 include low utilization 50% and high whitespace 50%. As shown, the standard cell region 504 of high utilization and low whitespace includes 6% Spare Gate Array Fill cells and 6% Spare Buffer cells (which are two types of ECO cells), with 15% Spare Gate Array Fill cells and 15% Spare Buffer cells in the standard cell regions 506 and 508 of low utilization and high whitespace. It should be understood that the example sizes, utilization, and whitespace values, and the example spare ECO cell values of standard cell regions 504, 506 and 508 are provided only for illustrative purposes.

In an embodiment, for example assume a threshold or target threshold density ratio of a spare ECO cell checking layer and a standard cell placement area checking layer is 0.10 or 10% for both Spare Gate Array Fill cells and Spare Buffer cells. At a block level of the illustrated standard cell based design block 500, an overall or global threshold density ratio resulting for the illustrated example is 10.5% of Spare Gate Array Fill cells, and 10.5% is Spare Buffer cells, meeting the overall block target ratio. The local spare cell density is 15% for both Spare Gate Array Fill cells and Spare Buffer cells of the standard cell regions 506 and 508 of low utilization and high whitespace, exceeds the target threshold density ratio 0.10 or 10%. However, over the large portion of the design block 500 including the standard cell region 504, the local spare cell density is 6% far lower than the target threshold density ratio 0.10 or 10%.

In an embodiment, illustrated example operations 510, 512, 514 of method 502 represent example tile results of windowed spare ECO cell density-based checking for spare ECO cells that can identify when the local density drops below a target threshold density value. As shown, the example tile results of windowed local spare ECO cell density based checking at blocks 510 and 512 are PASS with tiles located within or partly within the standard cell region 506 having the illustrated local spare cell density is 15% that is above the target threshold ratio 0.10 or 10%. While a FAIL results for windowed density-based checking at block 514 with the tile located within the standard cell region 504 having the illustrated local spare cell density is 6% that is below the target threshold density ratio 0.10 or 10%. While the overall global threshold density ratio 10.5% of block 500 exceeds the overall block target ratio of 10%, the windowed density based checking of method 500 effectively identifies when the local spare ECO cell density drops below a target threshold density ratio, which enables enforcing even spare ECO cell distribution across the regions of an IC layout.

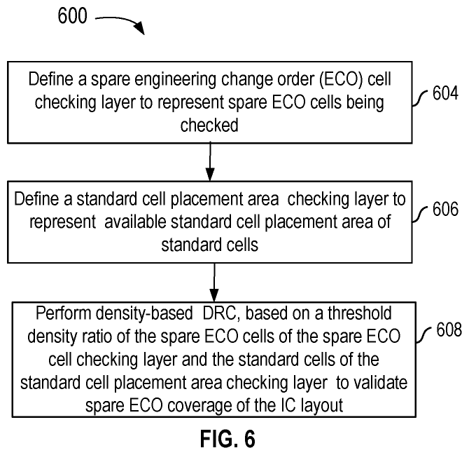

FIG. 6 illustrates features and operations of method 600 for implementing for implementing spare ECO cell coverage validation of a disclosed embodiment. At block 602, system 200 defines a spare engineering change order (ECO) cell checking layer to represent spare ECO cells being checked based on physical design data of an integrated circuit (IC) layout. In an embodiment, the spare ECO cells being checked comprises at least one of a gate array fill cell, a spare buffer, or a spare latch. For example, defining the spare ECO cell checking layer can be implemented by identifying the spare ECO cells based on cell shapes, or cell names in the physical design data of the IC layout, or based on a non-manufacturable marker layer of a spare ECO cell layout. In an embodiment, the spare ECO cell checking layer is dynamically generated in a checking run of the physical design data of the IC layout based on one of a cell name, or spare ECO cell shapes.

At block 604, system 200 defines a standard cell placement area checking layer to represent an available standard cell placement area of standard cells based on the physical design data. In an embodiment, defining the standard cell placement area checking layer includes identifying active circuit logic functions formed by interconnected standard cells, where the circuit logic functions can comprise multiple circuit rows, and voltage rails of the interconnected standard cells identified based on physical design data of the IC layout.

At block 606, system 200 performs density-based design rule checking (DRC), based on a threshold density ratio of the spare ECO cells of the ECO checking layer and the standard cells of the standard cell placement area checking layer, to validate spare ECO coverage of the IC layout. In an embodiment, performing the density-based DRC includes identifying the threshold density ratio of the spare ECO cells of the spare ECO cell checking layer and the standard cells of the standard cell placement area checking layer based on a predicted logical design stability of defined regions of the standard cell placement area checking layer. In an embodiment, performing density-based DRC includes identifying one or more of a tile size, a step size, one or more local threshold density ratios, or a global threshold density ratio; and performing windowed density-based DRC of spare ECO cells based on a target local threshold density ratio to identify a failure of the spare ECO cell coverage for an identified density ratio below the target local threshold density ratio.

While the foregoing is directed to embodiments of the present invention, other and further embodiments of the invention may be devised without departing from the basic scope thereof, and the scope thereof is determined by the claims that follow.

What is claimed is:

1. A method comprising:
defining a spare engineering change order (ECO) cell checking layer to represent spare ECO cells being checked based on physical design data of an integrated circuit (IC) layout;
defining a standard cell placement area checking layer to represent an available standard cell placement area of standard cells based on the physical design data; and
performing density-based design rule checking (DRC), based on a threshold density ratio of the spare ECO cells of the spare ECO cell checking layer and the standard cells of the standard cell placement area checking layer, to validate spare ECO coverage of the IC layout.

2. The method of claim 1, wherein the spare ECO cells being checked comprises at least one of a spare gate array fill cell, a spare buffer, or a spare latch.

3. The method of claim 1, wherein defining the spare ECO cell checking layer further comprises identifying the spare ECO cells based on cell shapes in the physical design data of the IC layout.

4. The method of claim 1, wherein defining the spare ECO cell checking layer further comprises identifying the spare ECO cells based on a cell name in the physical design data of the IC layout.

5. The method of claim 1, wherein defining the spare ECO cell checking layer further comprises identifying the spare ECO cells based on a non-manufacturable marker layer of a spare ECO cell layout.

6. The method of claim 1, wherein defining the spare ECO cell checking layer further comprises dynamically generating the spare ECO cell checking layer in a checking run of the physical design data of the IC layout based on one of a cell name, or spare ECO cell shapes.

7. The method of claim 1, wherein performing the density-based DRC further comprises identifying one or more of a tile size, a step size, one or more local threshold density ratios, or a global threshold density ratio.

8. The method of claim 7, further comprises performing a windowed density-based DRC check of spare ECO cells based on the threshold density ratio to identify failure of the spare ECO cell coverage for an identified density ratio below a target local threshold density ratio.

9. The method of claim 1, wherein defining a standard cell placement area checking layer further comprises identifying active circuit logic functions formed by interconnected standard cells, where the circuit logic functions comprise multiple circuit rows, and voltage rails of the interconnected standard cells identified based on the physical design data.

10. The method of claim 1, wherein performing density-based DRC further comprises identifying the threshold ratio of the spare ECO cells of the spare ECO cell checking layer and the standard cells of the standard cell placement area checking layer based on a predicted logical design stability of defined regions of the standard cell placement area checking layer.

11. A system, comprising one or more computer processors; and a memory containing a program which when executed by the one or more computer processors performs an operation, the operation comprising:
defining a spare engineering change order (ECO) cell checking layer to represent spare ECO cells being checked based on physical design data of an integrated circuit (IC) layout;
defining a standard cell placement area checking layer to represent an available standard cell placement area of standard cells based on the physical design data; and
performing density-based design rule checking (DRC), based on a threshold density ratio of the spare ECO cells of the spare ECO cell checking layer and the standard cells of the standard cell placement area checking layer, to validate spare ECO coverage of the IC layout.

12. The system of claim 11, wherein the spare ECO cells being checked comprises at least one of a gate array fill cell, a spare buffer, or a spare latch.

13. The system of claim 11, wherein defining the spare ECO cells checking layer further comprises dynamically generating the spare ECO cell checking layer in a checking run of the physical design data of the IC layout based on one of a cell name, or spare ECO cell shapes.

14. The system of claim 11, wherein performing the density-based DRC further comprises identifying one or more of a tile size, a step size, one or more local threshold density ratios, or a global threshold density ratio; and performing a windowed density-based DRC check using one or more of the tile size, the step size, the one or more local threshold density ratios, or the global threshold density ratio.

15. The system of claim 11, wherein performing density-based DRC further comprises identifying the threshold density ratio of the spare ECO cells of the spare ECO cell checking layer and the standard cells of the standard cell placement area checking layer based on a predicted logical design stability of defined regions of the standard cell placement area checking layer.

16. A computer program product comprising a computer-readable storage medium having computer-readable program code embodied therewith, the computer-readable program code executable by one or more computer processors to perform an operation comprising:
defining a spare engineering change order (ECO) cell checking layer to represent spare ECO cells being checked based on physical design data of an integrated circuit (IC) layout;
defining a spare engineering change order (ECO) cell checking layer to represent spare ECO cells being checked based on physical design data of an integrated circuit (IC) layout;
defining a standard cell placement area checking layer to represent an available standard cell placement area of standard cells based on the physical design data; and
performing density-based design rule checking (DRC), based on a threshold density ratio of the spare ECO cells of the spare ECO cell checking layer and the standard cells of the standard cell placement area checking layer, to validate spare ECO coverage of the IC layout.

17. The computer program product of claim 16, wherein the spare ECO cells being checked comprises at least one of a gate array fill cell, a spare buffer, or a spare latch.

18. The computer program product of claim 16, wherein defining the spare ECO cell checking layer further comprises dynamically generating the spare ECO cell checking layer in a checking run of the physical design data of the IC layout based on one of a cell name, or spare ECO cell shapes.

19. The computer program product of claim 16, wherein performing the density-based DRC further comprises identifying one or more of a tile size, a step size, one or more local threshold density ratios, or a global threshold density ratio; and performing windowed density-based DRC using one or more of the tile size, the step size, the one or more local threshold density ratios, or the global threshold density ratio.

20. The computer program product of claim 16, wherein performing density-based DRC further comprises identifying the threshold density ratio of the spare ECO cells of the spare ECO cell checking layer and the standard cells of the standard cell placement area checking layer based on a predicted logical design stability of defined regions of the standard cell placement area checking layer.
